(19) United States
(12) Patent Application Publication
(10) Pub. No.: US 2024/0105425 A1
(43) Pub. Date: Mar. 28, 2024

(54) SUBSTRATE PROCESSING APPARATUS AND METHOD OF PROCESSING SUBSTRATE BY USING THE SAME

(71) Applicant: Samsung Electronics Co., Ltd., Suwon-si (KR)

(72) Inventors: Seungwan Yoo, Suwon-si (KR); Jeongyeon Lee, Suwon-si (KR); Dohyung Kim, Suwon-si (KR); Jaehong Park, Suwon-si (KR); Dongchan Lim, Suwon-si (KR)

(21) Appl. No.: 18/244,571

(22) Filed: Sep. 11, 2023

(30) Foreign Application Priority Data
Sep. 27, 2022 (KR) 10-2022-0122867

(51) Int. Cl. H01J 37/32; H01L 21/02; H01L 21/67

(52) U.S. Cl. CPC H01J 37/32422; H01J 37/32522; H01J 37/32568; H01J 37/32715; H01L 21/02274; H01L 21/67098

(57) ABSTRACT

A substrate processing apparatus including a first chamber configured to accommodate a substrate therein and a second chamber including a heater provided in an internal space thereof, wherein the first chamber includes a target assembly configured to fix a target including a deposition material, a first ion gun configured to irradiate an ion beam onto the target to discharge deposition particles, which are ions of the deposition material, to the substrate, and a second ion gun configured to irradiate a hydrogen ion beam toward the substrate, the second ion gun includes a plasma generator configured to generate plasma, and a first grid electrode and a second grid electrode each configured to extract ions from the container, and the second chamber is configured to be provided with the substrate, on which the hydrogen ion beam has been irradiated, and perform thermal treatment on the substrate.

### CROSS-REFERENCE TO RELATED APPLICATION

This application is based on and claims priority under 35 U.S.C. § 119 to Korean Patent Application No. 10-2022-0122867, filed on Sep. 27, 2022, in the Korean Intellectual Property Office, the disclosure of which is incorporated by reference herein in its entirety.

### BACKGROUND

Aspects of the inventive concept relate to a substrate processing apparatus and a method of processing a substrate by using the substrate processing apparatus, and more particularly, to a substrate processing apparatus including an ion beam deposition device and an ion desorption device and a method of processing a substrate by using the substrate processing apparatus.

Metal wirings of semiconductor devices of the related art are mainly formed by a chemical vapor deposition (CVD) process and a physical vapor deposition (PVD) process. As the semiconductor devices have highly increased capacity and are highly integrated, the need for low-resistance metal wirings is increasing.

An ion beam deposition (IBD) process for decreasing a content of impurities and a crystallinity of film quality and performing a deposition process at a room temperature is a process for preventing a reduction in a crystallinity of a PVD process and oxidation caused by a reactive ion and has been widely used in a semiconductor manufacturing process.

### SUMMARY

Aspects of the inventive concept provide a substrate processing apparatus capable of removing hydrogen ions remaining on a thin film after a low-resistance thin film having sufficient crystallinity and a grain size is formed by irradiating a hydrogen ion beam before forming the thin film on a substrate, thereby preventing hydrogen brittleness.

Also, aspects of the inventive concept provide a method of processing a substrate, which may remove a hydrogen ion remaining on a thin film after a low-resistance thin film having sufficient crystallinity and a grain size is formed by irradiating a hydrogen ion beam before forming the thin film on a substrate, thereby preventing hydrogen brittleness.

According to an aspect of the inventive concept, there is provided a substrate processing apparatus including a first chamber configured to accommodate a substrate therein and a second chamber including a heater provided in an internal space thereof, wherein the first chamber includes a substrate assembly configured to fix the substrate, a target assembly configured to fix a target including a deposition material, a first ion gun configured to irradiate an ion beam onto the target to discharge a deposition particle, which is an ion of the deposition material, to the substrate, and a second ion gun configured to irradiate a hydrogen ion beam toward the substrate, the second ion gun includes a plasma generator configured to generate plasma, a container configured to accommodate the plasma, and a first grid electrode and a second grid electrode each configured to extract an ion from the container, and the second chamber is configured to be provided with the substrate, on which the hydrogen ion beam has been irradiated, and perform thermal treatment on the substrate.

According to another aspect of the inventive concept, there is provided a substrate processing apparatus including a first chamber configured to accommodate a substrate therein and a second chamber including a laser source provided in an internal space thereof, wherein the first chamber includes a substrate assembly configured to fix the substrate, a target assembly configured to fix a target including a deposition material, a first ion gun configured to irradiate an ion beam onto the target to discharge a deposition particle, which is an ion of the deposition material, to the substrate, and a second ion gun configured to irradiate a hydrogen ion beam toward the substrate, the second ion gun includes a plasma generator configured to generate plasma, a container configured to accommodate the plasma, and a first grid electrode and a second grid electrode each configured to extract an ion from the container, and the second chamber is configured to be provided with the substrate, on which the hydrogen ion beam has been irradiated, and perform thermal treatment on the substrate.

According to another aspect of the inventive concept, there is provided a substrate processing apparatus including a first chamber configured to accommodate a substrate therein and maintain vacuum pressure of about 10⁻¹ Torr to about 10⁻⁹ Torr and a second chamber including a heater provided in an internal space thereof, wherein the first chamber includes a substrate assembly configured to fix the substrate, a target assembly configured to fix a target including a deposition material, a first ion gun configured to irradiate an ion beam onto the target to discharge a deposition particle, which is an ion of the deposition material, to the substrate, and a second ion gun configured to irradiate a hydrogen ion beam toward the substrate, the second ion gun includes a plasma generator configured to generate plasma, a container configured to accommodate the plasma, and a first grid electrode and a second grid electrode each configured to extract an ion from the container, the second chamber is configured to be provided with the substrate, on which the hydrogen ion beam has been irradiated, and perform thermal treatment on the substrate, the heater is configured to supply heat to the substrate while maintaining a temperature of about 800° C. to about 1,200° C., the plasma generator is configured to be supplied with a processing gas so as to generate the plasma, and the processing gas includes hydrogen (H₂), helium (He), oxygen (O₂), nitrogen (N₂), argon (Ar), chromium (Cr), xenon (Xe), or a combination thereof, the processing gas is about 70% to about 100% in volume ratio of hydrogen (H₂), and the target includes one of tungsten (W), ruthenium (Ru), tantalum (Ta), titanium (Ti), aluminum (Al), copper (Cu), molybdenum (Mo), cobalt (Co), silver (Ag), platinum (Pt), nickel (Ni), chromium (Cr), gold (Au), germanium (Ge), magnesium (Mg), palladium (Pd), hafnium (Hf), zinc (Zn), vanadium (V), zirconium (Zr), a metal alloy thereof, and metal nitride thereof.

According to another aspect of the inventive concept, there is provided a method of processing a substrate, the method including placing a substrate in a first chamber, irradiating an ion beam toward a target provided in the first chamber by using a first ion gun, depositing deposition particles, discharged from the target, on a surface of the substrate to form a thin film, irradiating a hydrogen ion beam toward the thin film by using a second ion gun, placing the substrate, where the thin film on which the hydrogen ion beam has been irradiated is formed, in a second chamber, and performing thermal treatment on the substrate placed in the second chamber by using a heater.

### BRIEF DESCRIPTION OF THE DRAWINGS

Embodiments will be more clearly understood from the following detailed description taken in conjunction with the accompanying drawings in which:

FIG. 1 is a block diagram schematically illustrating a substrate processing apparatus according to an embodiment;

FIG. 2 is a diagram obtained by photographing a surface of a thin film formed on a substrate before irradiating the surface with hydrogen ions;

FIG. 3 is a diagram obtained by photographing a surface of a thin film formed on a substrate after irradiating the surface with hydrogen ions;

FIG. 4 is a diagram obtained by photographing a surface of a thin film when hydrogen ions remaining on the thin film formed on a substrate are not removed;

FIG. 5 is a block diagram schematically illustrating a first chamber according to an embodiment;

FIG. 6 is a block diagram schematically illustrating a second discharge chamber of a second ion gun, according to an embodiment;

FIG. 7 is a graph showing voltages of a plurality of grid electrodes, according to an embodiment;

FIG. 8 is a cross-sectional view schematically illustrating a second chamber according to an embodiment;

FIG. 9 is a block diagram schematically illustrating a substrate processing apparatus according to another embodiment;

FIG. 10 is a cross-sectional view schematically illustrating a third chamber according to another embodiment; and

FIG. 11 is a flowchart schematically illustrating a method of processing a substrate, according to an embodiment.

### DETAILED DESCRIPTION OF THE EMBODIMENTS

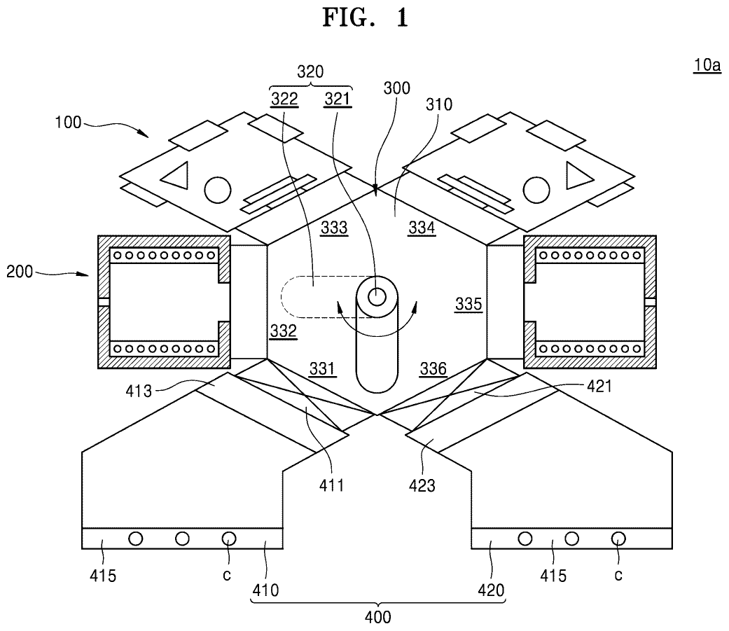

FIG. 1 is a block diagram schematically illustrating a substrate processing apparatus 10a according to an embodiment.

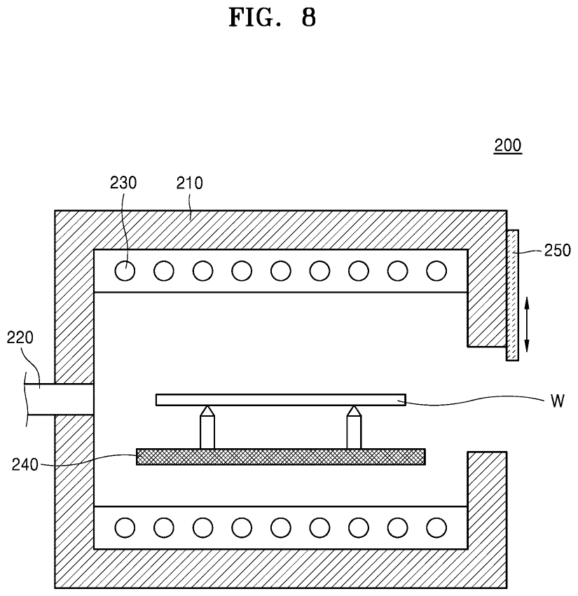

Referring to FIG. 1, the substrate processing apparatus 10a may include a first chamber 100 configured to accommodate a substrate and a second chamber 200 including a heater (see first of FIG. 8) provided in an internal space thereof.

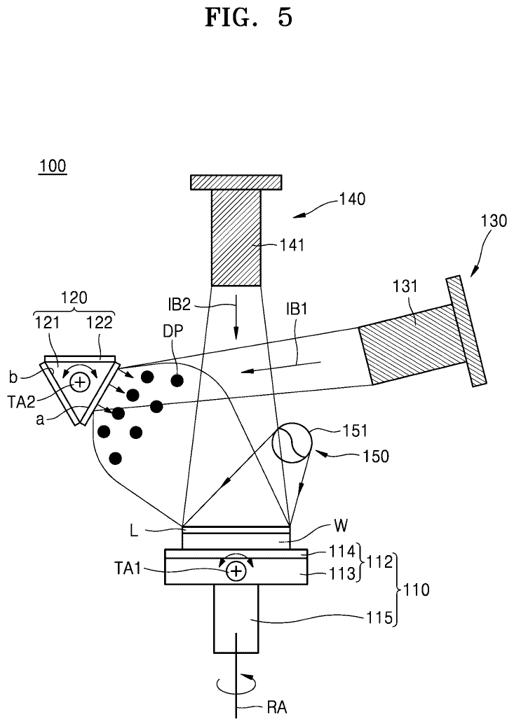

The first chamber 100 may include a substrate assembly (see 110 of FIG. 5) which fixes a substrate W, a target assembly (see 120 of FIG. 5) which fixes a target including a deposition material, a first ion gun (see 130 of FIG. 5) which irradiates an ion beam onto the target to discharge a deposition particle, which is an ion of the deposition material, to the substrate W, and a second ion gun (see 140 of FIG. 5) which irradiates a hydrogen ion beam toward the substrate W. Subsequently, the second chamber 200 may be supplied with the substrate W on which the hydrogen ion beam has been irradiated and may perform thermal treatment on the substrate W.

The first chamber 100 and the second chamber 200 will be described below in detail with reference to the drawings.

According to an embodiment, the substrate processing apparatus 10a may include a transport device 300 which includes a substrate handle 320, at least one substrate accommodating device 400 which is disposed at one side portion of the transport device 300 and accommodates a plurality of substrates, and at least one first chamber 100 which is disposed at the other side portion of the transport device 300 and performs an ion beam deposition process on the substrate W loaded from the substrate accommodating device 400 by the substrate handle 320 to form a thin film L.

According to an embodiment, the transport device 300 may include a transport chamber 310 having a polygonal cylinder shape and the substrate handle 320 which is fixed to a center portion of the transport chamber 310 and is capable of rotating by about 360 degrees.

The transport chamber 310 may be provided in a hexagonal pillar shape and may include first to sixth side surfaces 331 to 336. The transport chamber 310 may be connected to two first chambers 100, two second chambers 200, and two substrate accommodating devices 400. Therefore, two ion beam deposition processes and two hydrogen desorption processes may be performed independently and simultaneously.

According to an embodiment, the substrate handle 320 may include a fixing shaft 321 which is fixed to a center of the transport chamber 310 and a transport arm 322 which rotates along the fixing shaft 321. The transport arm 322 may transport a substrate while moving between the substrate accommodating device 400 and the first chamber 100, based on a processing algorithm of an ion beam process.

The substrate accommodating device 400 may include a first substrate stack 410 which is disposed to be connected to the first side surface 331 of the transport device 300 and accommodates a plurality of deposition target substrates W and a second substrate stack 420 which is disposed to be connected to the sixth side surface 336 of the transport device 300 and accommodates a deposition-completed substrate where a thin film is formed. The first substrate stack 410 may be selectively connected to the transport device 300 through an inlet gate 411, and the second substrate stack 420 may be selectively connected to the transport device 300 through an outlet gate 421.

According to an embodiment, a substrate where a thin film deposition process and a hydrogen ion processing process are completed in the first chamber 100 may be transported to the second chamber 200 through the transport device 300. In detail, the substrate handle 320 may be configured to load and unload a substrate, and the substrate where the thin film deposition process and the hydrogen ion processing process are completed in the first chamber 100 may be unloaded by the substrate handle 320. Subsequently, the substrate handle 320 may transport a substrate to the second chamber 200, and then, the substrate may be loaded into a transport unit included in the second chamber 200.

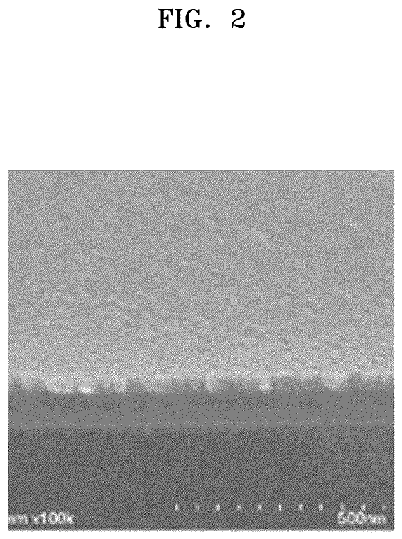

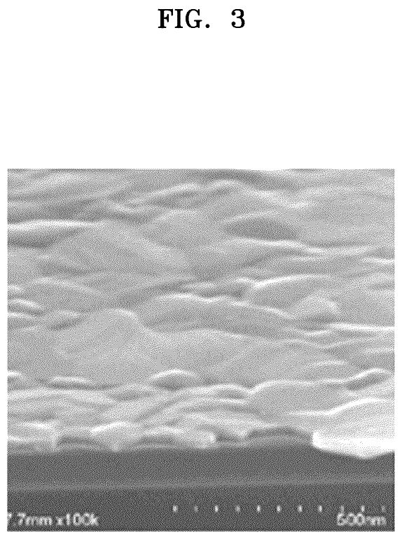

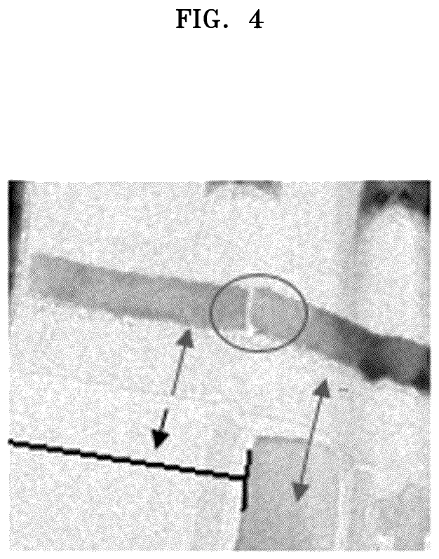

FIG. 2 is a diagram obtained by photographing a surface of a thin film formed on a substrate before irradiating a hydrogen ion, and FIG. 3 is a diagram obtained by photographing a surface of a thin film formed on a substrate after irradiating a hydrogen ion. FIG. 4 is a diagram obtained by photographing a surface of a thin film when a hydrogen ion remaining on a thin film formed on a substrate is not removed.

Referring to FIG. 2, when a hydrogen ion is not irradiated onto a thin film formed on a substrate, a grain size of the thin film may be formed to be small, and thus, crystallinity may be reduced. When a grain size is small, it may be difficult to secure sufficient crystallinity, and due to this, there may be a limitation in decreasing a resistance of a thin film. Accordingly, an ion beam deposition process of the related art may be difficult to form a metal wiring of a high-capacity and highly-integrated semiconductor device.

Referring to FIG. 3, in a case where a hydrogen ion is irradiated onto a thin film formed on a substrate, it may be seen that a grain size of the thin film is formed to be large, compared to FIG. 2. When a grain size is large, sufficient crystallinity may be secured, and thus, a resistance of a thin film may increase. However, when a hydrogen ion is irradiated onto a substrate, a probability that hydrogen brittleness occurs may increase. This will be described below in detail with reference to the drawings.

FIG. 4 is a diagram obtained by photographing a surface of a thin film when a hydrogen ion remaining on a thin film formed on a substrate is not discharged.

Referring to FIG. 4, when a hydrogen ion is irradiated onto a substrate, a probability that hydrogen brittleness occurs may increase. Hydrogen brittleness may denote a phenomenon where ductility or toughness is reduced by hydrogen absorbed by a metal material and damage increases even without plastic deformation. Hydrogen brittleness may occur when a hydrogen ion is bonded to a void included in a thin film, and thus, a method for decreasing a void in a thin film and a method for desorbing a hydrogen ion may be needed.

FIG. 5 is a block diagram schematically illustrating a first chamber 100 according to an embodiment.

Referring to FIG. 5, the first chamber 100 may include a substrate assembly 110 which fixes a substrate W which is a deposition target, a target assembly 120 which is disposed to be inclined with respect to the substrate W and fixes a target 122 including a deposition material, a first ion gun 130 which irradiates an ion beam IB1 onto the target 122 to discharge a deposition particle DP, which is an ion of the deposition material, to the substrate W, a second ion gun 140 which irradiates a hydrogen ion beam IB2 toward the substrate W, and a substrate heater 150 which heats the substrate W to increase a crystallinity of a thin film L formed by depositing the deposition particle DP on the substrate W. The first chamber 100 may maintain vacuum pressure of about 10⁻¹ Torr to about 10⁻⁹ Torr. Because the first chamber 100 maintains vacuum pressure of about 10⁻¹ Torr to about 10⁻⁹ Torr, the deposition particle DP may move to the substrate W without the loss of kinetic energy substantially.

According to an embodiment, the substrate assembly 110 may include a substrate fixing unit 112 which fixes the substrate W and tilts by a certain angle and a support unit 115 which supports the substrate fixing unit 112 and rotates about a rotational axis thereof to rotate the substrate fixing unit 112. The substrate fixing unit 112 may include a fixing unit body 113 which includes a conductive material, having excellent conductivity, such as Al and a fixing chuck 114 which is disposed on an upper surface of the fixing unit body 113 and fixes the substrate W. The fixing unit body 113 may be provided to have a size and a shape each enabling the fixing chuck 114 to be accommodated therein, and a guide electrode (not shown) for inducing the deposition particle DP to the substrate W may be selectively provided therein.

According to an embodiment, the fixing unit body 113 may be disposed so that the fixing unit body 113 rotates about a tilting axis TA1 extending in parallel with an upper surface of the fixing unit body 113 and thus is inclined by a substrate inclination angle of a certain range. For example, the fixing unit body 113 may rotate clockwise and counterclockwise about the tilting axis TA1 with respect to a horizontal surface vertical to the support unit 115, and thus, may be disposed to be inclined by the substrate inclination angle. Based on a rotation of the fixing unit body 113, the substrate W fixed to the fixing chuck 114 may rotate together, and thus, the substrate W may be disposed to be inclined by the substrate inclination angle. For example, a substrate slope may be determined to maximize efficiency where the deposition particle DP discharged from the target 122 is deposited on a surface of the substrate W. The substrate slope may be appropriately adjusted based on a movement direction of the deposition particle DP. In an embodiment, an example is disclosed where the substrate W is horizontally disposed and a substrate slope thereof is 0 degrees, but the substrate W may be set to have various substrate slopes so that a deposition efficiency of the deposition particle DP is maximized based on a position of the target 122.

According to an embodiment, the fixing chuck 114 may be provided in a disk shape including an insulation material such as ceramic and may fix a deposition target substrate W to an upper surface by using various substrate fixing means included therein. The fixing chuck 114 may be configured as an electro static chuck (ESC) including a pair of polyimide-based films (not shown) and a conductive thin film (not shown) which is disposed between the polyimide-based films and is connected to a high-voltage direct current (DC) power source. However, the fixing chuck 114 may use various fixing means such as a clamp mechanically fixing a substrate, in addition to the ESC described above.

The support unit 115 may extend from one side of the first chamber 100 and may rotate about a rotational axis RA thereof to rotate the substrate fixing unit 112. For example, the support unit 115 may be configured as a support bar which extends toward an internal space of the first chamber 100 from a side portion of the first chamber 100 and is connected with a center portion of the fixing unit body 113.

The support unit 115 may selectively adjust an extension height extending toward an internal space of a process chamber to adjust a fixed position of the substrate W. Also, the support unit 115 may be configured to rotate about the rotational axis RA passing through a center thereof and a center of the fixing unit body 113 and may rotate the substrate W while an ion beam deposition process is being performed. Particularly, the fixing unit body 113 may rotate in a state where the substrate W is fixed by an appropriate substrate slope, based on tilting of the fixing unit body 113, and thus, the uniformity of the thin film L formed on the substrate W may be maximized.

According to an embodiment, the target assembly 120 may include at least one target 122 which is disposed to be inclined by a certain angle with respect to the substrate W and includes a deposition material. For example, the target assembly 120 may include a target body 121 which rotates about a target axis TA2 and has a polygonal shape and at least one target 122 which is individually fixed to the target body 121 and includes a deposition material. The target body 121 may be provided in the form of a prism including a plurality of side surfaces and may be configured to rotate about the target axis TA2 passing through a center of the prism. Accordingly, the side surfaces of the target body 121 may configure a deposition geometry between the substrate W and the first ion gun 130 and may be configured with a target surface a where the deposition particle DP generated by the ion beam IB1 moves to the substrate W and a plurality of standby surfaces b. Abrasion of the target 122 and the uniformity of the thin film L formed on the substrate W may be optimized based on the deposition geometry. Accordingly, the target surface a and the standby surface b may switch therebetween, based on a rotation of the target body 121. For example, the target body 121 may be provided in a triangular pillar shape including one target surface a and two standby surfaces b, and the target 122 may be mounted up to a maximum of three. However, it is obvious that the number of standby surfaces b is changed based on the number of desired targets 122. For example, when the target body 121 is provided in an octagonal pillar shape, the target 122 may be mounted up to a maximum of eight.

The target 122 may be mounted on at least one of the target surface a and the standby surface b. For example, the target 122 may include a deposition material and may be provided as a plate which covers the target surface a or the standby surface b, and the deposition particle DP which is a deposition material ion may be generated by a collision with a high-energy ion beam injected from the first ion gun 130. Accordingly, the target 122 may include various materials, based on the kind of a thin film deposited on the substrate W. The plurality of targets may include the same material, and the thin film L may be formed of a single thin film. On the other hand, the plurality of targets may include different materials, and the thin film L may be formed of a multi-layer film including different compositions.

Optionally, the target 122 may rotate in parallel with the target surface a by using a separate rotary member (not shown), and thus, the abrasion non-uniformity of the target 122 may be prevented. For example, the target 122 may include a low-resistance metal material, and thus, a low-resistance metal layer may be formed on the substrate W. For example, the low-resistance metal material may include one of tungsten (W), ruthenium (Ru), tantalum (Ta), titanium (Ti), aluminum (Al), copper (Cu), molybdenum (Mo), cobalt (Co), silver (Ag), platinum (Pt), nickel (Ni), chromium (Cr), gold (Au), germanium (Ge), magnesium (Mg), palladium (Pd), hafnium (Hf), zinc (Zn), vanadium (V), zirconium (Zr), a metal alloy thereof, and metal nitride thereof. Therefore, in an embodiment, the deposition particle DP may include a metal atom or ion.

According to an embodiment, the first ion gun 130 may irradiate the ion beam IB1 onto the target 122 to discharge the deposition particle DP to the substrate W. The first ion gun 130 may generate the ion beam D3 which has high energy and is irradiated at a certain inclination angle with respect to the target 122, based on a beam source gas supplied from an external beam source.

For example, the first ion gun 130 may include a first discharge chamber 131 which ionizes the beam source gas and an ion grid (not shown) which is connected to the first discharge chamber 131 and accelerates ions of the beam source gas to generate the ion beam IB including rectilinear high-energy ions facing the target assembly 120.

The first discharge chamber 131 may discharge and ionize the beam source gas supplied from the beam source. For example, by applying a strong electric field between a discharge cathode and a gas supply terminal, the beam source gas may be discharged, or the beam source gas may be formed in a plasma state, and thus, may be ionized. For example, the first discharge chamber 131 may include a radio frequency inductively coupled plasma (RFICP) generator. Ions of the beam source gas may be accelerated by an electromagnetic force applied to the first discharge chamber 131, and thus, may be generated as a high-energy ion beam. The beam source gas may include one of argon (Ar), chromium (Cr), neon (Ne), and xenon (Xe), and thus, may maximize kinetic energy of the ion beam IB1 and may minimize pollution caused by impurities.

According to an embodiment, when the high-energy ion beam D31 collides with the target 122, the deposition particle DP may be discharged from a surface of the target 122 and may move to the substrate W. Based on the deposition geometry, the deposition particle DP discharged by a collision between the ion beam IB1 and the target 122 and may move toward the substrate W, and thus, the thin film L may be formed on the substrate W by an ion beam deposition (IBD) process.

According to an embodiment, a second ion gun 140 for irradiating a hydrogen ion beam IB2 toward the substrate W disposed on the substrate assembly 110 may be included in the first chamber 100. The second ion gun 140 may include a plurality of grid electrodes which are connected to the second discharge chamber 141 for ionizing a processing gas and accelerates ions of the processing gas to generate the hydrogen ion beam IB2 including rectilinear high-energy ions facing the substrate W. The plurality of grid electrodes will be described below in detail with reference to the drawings.

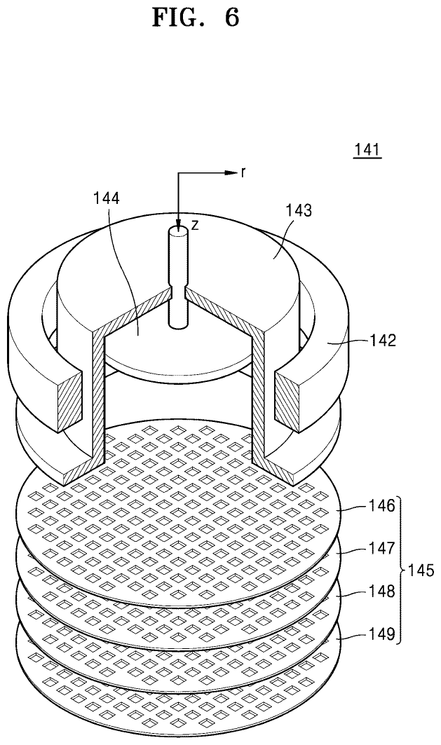

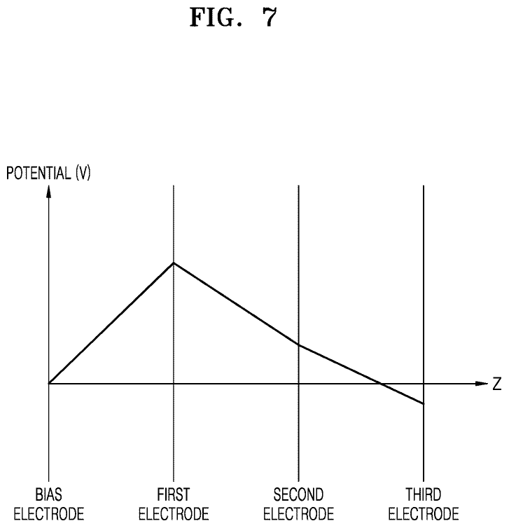

FIG. 6 is a block diagram schematically illustrating a second discharge chamber 141 of a second ion gun 140, according to an embodiment, and FIG. 7 is a graph showing voltages of a plurality of grid electrodes 146 to 149, according to an embodiment.

Referring to FIG. 6, the second discharge chamber 141 of the second ion gun 140 may include a plasma generator 142 which generates plasma including an ion, an electron, and a neutral gas, a container 143 which accommodates the plasma, a bias electrode 144 which is disposed in the container 143, and an ion extractor 145 which extracts ions from the container 143, and the bias electrode 144 may increase energy of an ion.

The plasma generator 142 may use at least one of inductively coupled plasma (ICP), capacitively coupled plasma (CCP), direct current (DC) discharge plasma, and electron cyclotron resonance (ECR) plasma, which correspond to a general plasma generating method. Also, an external magnetic flux density B may be used for increasing discharge efficiency. The external magnetic flux density B may be generated by an electromagnet (not shown) or a permanent magnet (not shown).

According to an embodiment, the plasma generator 142 may generate plasma by irradiating ultraviolet (UV) onto the neutral gas, or may heat a gas at a high temperature to generate the plasma. The plasma generating method may be variously modified.

According to an embodiment, the plasma generator 142 may be supplied with a processing gas so as to generate the plasma. For example, the processing gas may include hydrogen (H₂), helium (He), oxygen (O₂), nitrogen (N₂), argon (Ar), chromium (Cr), xenon (Xe), or a combination thereof. The processing gas may be about 70% to about 100% in volume ratio of hydrogen (H₂).

According to an embodiment, the plasma generator 142 may include a power source (not shown) and a load (not shown) which is supplied with energy from the power source to apply energy to plasma, and the load may include at least one of an electrode and an antenna. Accordingly, the load may include one electrode and one antenna, or may include a plurality of antennas. The power source may include at least one of a DC power source, an alternating current (AC) power source, a radio frequency (RF) power source, and a microwave power source. The power source may supply energy up to the load through a transmission line or a wave guide. The load may be disposed in or outside the container 143. The transmission line may include at least one of a wave guide, a bus bar, a single wire, two wires, and a strip line. A matching network may be disposed between the power source and the load.

The load may generate electrostatic electric field intensity Es to generate the plasma, or may generate inductive electric field intensity Ein to generate the plasma. When the load is an electrode, the electrode may be disposed in or outside the container 143. The electrode may include a conductive material. Also, the electrode may further include an insulation layer or a semiconductor layer. The insulation layer may include oxide aluminum (Al₂O₃) or quartz (Sift). The semiconductor layer may include silicon (Si).

According to an embodiment, all or a portion of the container 143 may be insulating properties. For example, the load may be disposed outside an insulating portion of the container 143. The load disposed outside the container 143 may generate electrostatic electric field intensity or inductive electric field intensity to generate plasma. An insulator of the container 143 may include at least one of Si, quartz, glass, and (Al₂O₃). A shape of the container 143 may have at least one of a bell jar shape, a cylindrical shell shape, and a polygonal shell shape. A shape of the container 143 is not limited thereto and may be variously changed.

Pressure of the container 143 may be lower than atmospheric pressure. The plasma may include a positive ion, a negative ion, a neutral gas, and an electron. The neutral gas may include at least one of Ar, He, H₂, O₂, Cl₂, SF₆, and CF₄. The neutral gas may be supplied to the container 143 through an external gas supply device (not shown).

According to an embodiment, the bias electrode 144 may be disposed in the container 143. The bias electrode 144 may include a conductor. The bias electrode 144 may include at least one of molybdenum (Mo), carbon (C), and diamond like carbon (DLC). The bias electrode 144 may include a material robust to a corrosion resistance and sputtering. In detail, the bias electrode 144 may be carbon, and a surface thereof may be coated with DLC. Power may be connected to the bias electrode 144. The power may be at least one of DC power, AC power, and RF power. The power of the bias electrode 144 may operate in a pulse form. A voltage applied to the bias electrode 144 may be a negative voltage or a positive voltage. A maximum voltage applied to the bias electrode 144 may depend on a density of plasma and pressure of the container 143.

According to an embodiment, the second ion gun 140 may include the ion extractor 145, and the ion extractor 145 may include the plurality of grid electrodes 146 to 149. That is, the second ion gun 140 may include a first grid electrode 146, a second grid electrode 147, a third grid electrode 148, and a fourth grid electrode 149, which are configured to extract an ion from the container 143. The first grid electrode 146, the second grid electrode 147, the third grid electrode 148, and the fourth grid electrode 149 may be arranged apart from one another and may be electrically insulated from one another. The first grid electrode 146 may be electrically floated. The first grid electrode 146 may be electrically floated in that the first grid electrode 146 may acquire a stray voltage, dependent on capacitive coupling, when in close proximity to an electric field. Also, a negative acceleration voltage may be applied to the second grid electrode 147. A plasma potential of the container 143 may be higher than a voltage of the bias electrode 144. Therefore, a positive ion of the plasma may have potential energy which is higher than or equal to an application voltage of the bias electrode 144.

According to an embodiment, the plurality of grid electrodes 146 to 149 may include at least one of a metal mesh, a carbon mesh, and a plated micro capillary. The metal mesh may include at least one of Mo, W, Ni, Au, Ag, and an alloy thereof. A structure of each of the plurality of grid electrodes 146 to 149 may be selected to have an appropriate shape, based on a computer simulation, theoretical calculation, and an experiment result. The carbon mesh may be formed by a photolithography process and a patterning process or a sintering process. A structure and a material of each of the plurality of grid electrodes 146 to 149 may be variously changed.

According to an embodiment, a positive ion of the plasma may be accelerated through the floated first grid electrode 146 and the second grid electrode 147 to which a negative voltage is applied. That is, the potential energy of a positive ion may be converted into kinetic energy. On the other hand, the positive ion may be decelerated between the second grid electrode 147 and the third grid electrode 148. As a result, the positive ion of the plasma may pass through the ion extractor 145 and may obtain kinetic energy corresponding to a voltage applied to the bias electrode 144.

Furthermore, a positive voltage may be applied to the second grid electrode 147. For example, the positive voltage may be decelerated between the first grid electrode 146 and the second grid electrode 147. This will be described below in detail with reference to the drawings.

Referring to FIG. 7, a positive voltage may be applied to the second grid electrode 147. For example, a hydrogen ion having a positive electric charge may be decelerated between the first grid electrode 146 and the second grid electrode 147 by a repulsive force. When a number of hydrogen ions have potential energy and face the substrate W, a number of voids may occur in a thin film formed on the substrate W. Accordingly, by applying a positive voltage to the second grid electrode 147, potential energy of a hydrogen ion may decrease, and thus, the occurrence of a number of voids in the thin film may be prevented. For example, a positive voltage applied to the second grid electrode 147 may be about 60 V to about 1,000 V, and a voltage which is higher than that of the first grid electrode 146 may be applied to the second grid electrode 147. A voltage which is lower than that of the second grid electrode 147 may be applied to the third grid electrode 148. When an excessively high positive voltage is applied to the second grid electrode 147, sufficient positive hydrogen ions may not reach the substrate W, and thus, a positive voltage applied to the second grid electrode 147 may increase from about 60 V until reaching an optimal voltage.

FIG. 8 is a cross-sectional view schematically illustrating a second chamber 200 according to an embodiment.

Referring to FIG. 8, the second chamber 200 may include a housing 210, a gas line 220 connected to the housing 210, a heater 230 provided in the housing 210, and a transport unit 240 which loads/unloads a semiconductor substrate W into/from the housing 210. The second chamber 200 may be a single-type device. That is, the second chamber 200 may perform a thermal treatment process on one substrate W once. The housing 210 may provide a space where a process is performed on the substrate W. The gas line 220 may be connected to the housing 210. Also, a door 250 which acts as a path for loading/unloading the substrate W may be installed in the housing 210. The door 250 may prevent the penetration of external air into the housing 210 in performing a thermal treatment process and may prevent the transport unit 240 from deviating from the housing 210. The heater 230 may be configured to supply heat to the substrate W. The heater may be configured to supply heat to the substrate W while maintaining a temperature of about 800° C. to about 1,200° C. The second chamber 200 may supply high-temperature heat to a substrate W, on which hydrogen ion processing has been performed, through the second ion gun 140, and thus, may desorb a hydrogen ion remaining on a thin film. Because a hydrogen ion remaining on a thin film is desorbed, the occurrence of hydrogen brittleness due to residual hydrogen may be prevented.

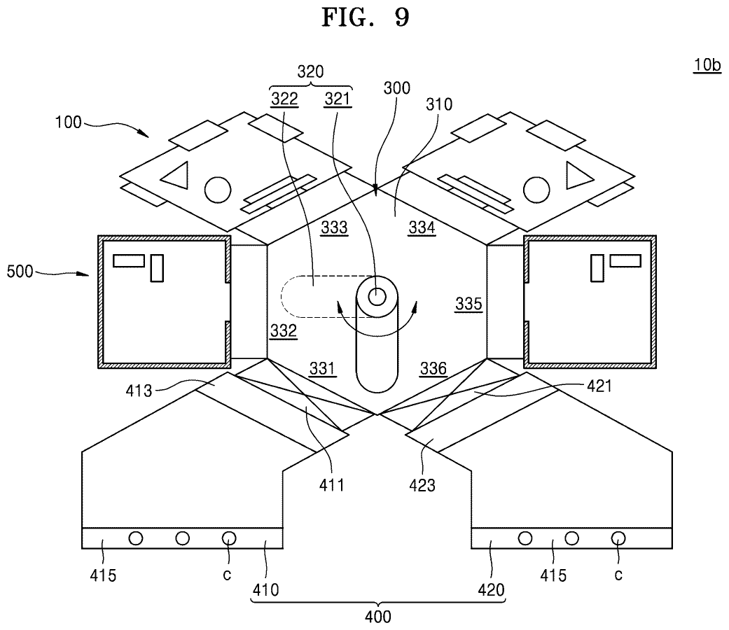

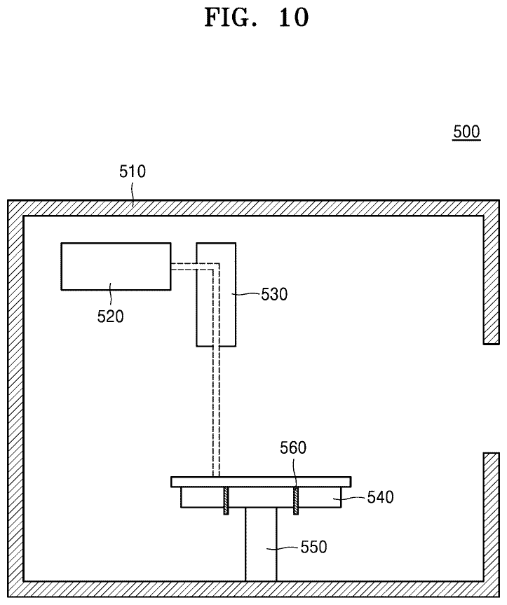

FIG. 9 is a block diagram schematically illustrating a substrate processing apparatus 10b according to another embodiment, and FIG. 10 is a cross-sectional view schematically illustrating a third chamber 500 according to another embodiment.

In detail, except for that the substrate processing apparatus 10b includes the third chamber 500 which anneals a substrate by using a laser source 520 instead of a heater 230, the substrate processing apparatus 10b may be the same as the substrate processing apparatus 10a of FIG. 1. In FIGS. 9 and 10, the same reference numerals as FIG. 2 will be briefly described, or descriptions thereof may be omitted.

Referring to FIG. 9, the substrate processing apparatus 10b may include a first chamber 100 configured to accommodate a substrate and a second chamber 200 including a laser source (see 520 of FIG. 10) provided in an internal space thereof.

Referring to FIG. 10, the third chamber 500 may include a housing 510 for accommodating a substrate, a chuck 540 which is disposed on a bottom portion of the third chamber 500, a chuck supporting unit 550 which supports the chuck 540, a laser source 520 which generates a laser beam, and a beam delivery optical structure 530 for transferring the laser beam to an upper surface of a loaded substrate.

According to an embodiment, the chuck 540 may be disposed on the bottom portion of the third chamber 500. The chuck 540 may include an upper surface to which a substrate W is loaded. For example, the chuck 540 may be an electrostatic chuck which fixes the loaded substrate with an electrostatic force. On the other hand, the chuck 540 may be a vacuum chuck which fixes the loaded substrate W with vacuum pressure.

According to an embodiment, the third chamber 500 may include a plurality of lift pins 560 which pass through the chuck 540. The lift pins 560 may be used in loading and unloading the substrate W. A length of each of the lift pins 560 may be greater than a thickness of the chuck 540.

According to an embodiment, unlike the second chamber 200 illustrated in FIG. 2, the third chamber 500 may perform a thermal treatment process on the substrate W by using the laser source 520 instead of the heater 230. In detail, the substrate W on which a hydrogen ion beam has been irradiated in the first chamber 100 illustrated in FIG. 8 may be supplied to the third chamber 500 through the transport device 300. Subsequently, the substrate W may be thermally processed by the laser source 520, and residual hydrogens on a thin film formed on the substrate W may be desorbed. As a result of the residual hydrogens being desorbed from the thin film, a probability that hydrogen brittleness occurs may be reduced.

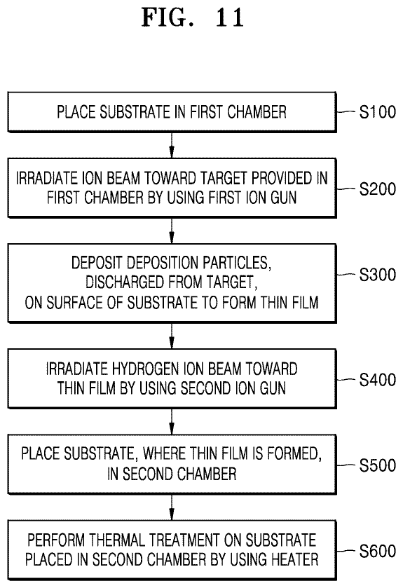

FIG. 11 is a flowchart schematically illustrating a substrate processing method according to an embodiment. In detail, the substrate processing method may be a substrate processing method using the substrate processing apparatus 10a illustrated in FIG. 1. Referring to FIGS. 1, 5, 8, and 11, the substrate processing method may include an operation S100 of placing the substrate W in the first chamber 100. The substrate W may be loaded into the first chamber 100 by the substrate handle 320 included in the transport device 300. In detail, the substrate fixing unit 112 included in the first chamber 100 may fix the substrate W and may tilt by a certain angle.

The substrate processing method may include an operation S200 of irradiating the ion beam IB1 toward the target 122 of the first chamber 100 by using the first ion gun 130. The target 122 may be mounted on at least one of the target surface a and the standby surface(s) b. For example, the target 122 may include a deposition material and may be provided as a plate which covers the target surface a or the standby surface(s) b, and the deposition particle DP which is a deposition material ion may be generated by a collision with a high-energy ion beam (e.g., ion beam IB1) injected from the first ion gun 130. Accordingly, the target 122 may include various materials, based on the kind of a thin film deposited on the substrate W. The target 122 may include a low-resistance metal material, and thus, a low-resistance metal layer may be formed on the substrate W. For example, the low-resistance metal material may include one of tungsten (W), ruthenium (Ru), tantalum (Ta), titanium (Ti), aluminum (Al), copper (Cu), molybdenum (Mo), cobalt (Co), silver (Ag), platinum (Pt), nickel (Ni), chromium (Cr), gold (Au), germanium (Ge), magnesium (Mg), palladium (Pd), hafnium (Hf), zinc (Zn), vanadium (V), zirconium (Zr), a metal alloy thereof, and metal nitride thereof.

Subsequently, the substrate processing method may include an operation S300 of depositing the deposition particles DP, discharged from the target 122, on a surface of the substrate W to form the thin film L. The plurality of targets may include the same material, and the thin film L may be formed of a single thin film. On the other hand, the plurality of targets may include different materials, and the thin film L may be formed of a multi-layer film including different compositions.

Subsequently, the substrate processing method may include an operation S400 of irradiating the hydrogen ion beam IB2 toward the thin film L by using the second ion gun 140. When a hydrogen ion is irradiated onto a thin film formed on a substrate, a grain size of the thin film may be formed to be large. When a grain size of a thin film is large, sufficient crystallinity may be secured, and thus, a resistance of a thin film may increase. A plurality of grid electrodes may be included in the second ion gun 140. For example, a positive voltage may be applied to some of a plurality of grid electrodes, and hydrogen ions having a positive electric charge may be reduced by a repulsive force of a grid to which a positive voltage is applied. A hydrogen ion, which is decelerated by a repulsive force of a grid to which a positive voltage is applied, may have low potential energy, and thus, the occurrence of a number of voids in a thin film may be prevented. In the operation S400 of irradiating the hydrogen ion beam IB2 toward the thin film L by using the second ion gun 140, the first chamber 100 may maintain vacuum pressure of about 10⁻¹ Torr to about 10⁻⁹ Torr.

Subsequently, the substrate processing method may include an operation S500 of placing the substrate W, where the thin film L on which the hydrogen ion beam IB2 has been irradiated is formed, in the second chamber 200. A substrate, on which a thin film deposition process and a hydrogen ion processing process have been performed, may be transported to the second chamber 200 through the transport device 300. In detail, the operation S500 of placing the substrate W, where the thin film L on which the hydrogen ion beam IB2 has been irradiated is formed, in the second chamber 200 may be performed by a transport device configured to transport the substrate W. The substrate handle 320 included in the transport device 300 may unload the substrate W into the first chamber 100. Subsequently, the substrate handle 320 may transport a substrate to the second chamber 200, and then, the substrate may be loaded into a transport unit included in the second chamber 200.

Subsequently, the substrate processing method may include an operation S600 of performing thermal treatment on the substrate W placed in the second chamber 200 by using a heater. The heater 230 may be configured to supply heat to the substrate W. The heater may be configured to supply heat to the substrate W while maintaining a temperature of about 800° C. to about 1,200° C. The second chamber 200 may supply high-temperature heat to a substrate W, on which hydrogen ion processing has been performed, through the second ion gun 140, and thus, may desorb a hydrogen ion remaining on a thin film. Because a hydrogen ion remaining on a thin film is desorbed, the occurrence of hydrogen brittleness due to residual hydrogen may be prevented.

Hereinabove, exemplary embodiments have been described in the drawings and the specification. Embodiments have been described by using the terms described herein, but this has been merely used for describing the inventive concept and has not been used for limiting a meaning or limiting the scope of the inventive concept defined in the following claims. Therefore, it may be understood by those of ordinary skill in the art that various modifications and other equivalent embodiments may be implemented from the inventive concept. Accordingly, the spirit and scope of the inventive concept may be defined based on the spirit and scope of the following claims.

While the inventive concept has been particularly shown and described with reference to embodiments thereof, it will be understood that various changes in form and details may be made therein without departing from the spirit and scope of the following claims.

1. A substrate processing apparatus comprising:
a first chamber configured to accommodate a substrate therein; and
a second chamber including a heater provided in an internal space thereof,
wherein the first chamber comprises
a substrate assembly configured to fix the substrate,
a target assembly configured to fix a target including a deposition material,
a first ion gun configured to irradiate an ion beam onto the target to discharge deposition particles, which are ions of the deposition material, to the substrate, and
a second ion gun configured to irradiate a hydrogen ion beam toward the substrate,
wherein the second ion gun comprises
a plasma generator configured to generate plasma,
a container configured to accommodate the plasma, and
a first grid electrode and a second grid electrode each configured to extract ions from the container, and
wherein the second chamber is configured to be provided with the substrate, on which the hydrogen ion beam has been irradiated, and perform thermal treatment on the substrate.

2. The substrate processing apparatus of claim 1, wherein the second grid electrode is disposed apart from the first grid electrode and receives a positive voltage of about 60 V to about 1,000 V.

3. The substrate processing apparatus of claim 1, wherein the second grid electrode receives a voltage which is higher than a voltage of the first grid electrode.

4. The substrate processing apparatus of claim 1, wherein the second grid electrode is electrically insulated from the first grid electrode.

5. The substrate processing apparatus of claim 1, wherein the first grid electrode is electrically floated.

6. The substrate processing apparatus of claim 1, wherein each of the first grid electrode and the second grid electrode comprises at least one of a metal mesh, a carbon mesh, and a plated micro capillary.

7. The substrate processing apparatus of claim 1, wherein the heater is configured to supply heat to the substrate while maintaining a temperature of about 800° C. to about 1,200° C.

8. The substrate processing apparatus of claim 1, wherein the plasma generator is configured to receive a processing gas so as to generate the plasma, and
the processing gas comprises hydrogen (H₂), helium (He), oxygen (O₂), nitrogen (N₂), argon (Ar), chromium (Cr), xenon (Xe), or a combination thereof.

9. The substrate processing apparatus of claim 8, wherein the processing gas is about 70% to about 100% in volume ratio of hydrogen (H₂).

10. The substrate processing apparatus of claim 1, wherein the first chamber is configured to maintain a vacuum pressure of about 10⁻¹ Torr to about 10⁻⁹ Torr.

11. The substrate processing apparatus of claim 1, wherein the target comprises one of tungsten (W), ruthenium (Ru), tantalum (Ta), titanium (Ti), aluminum (Al), copper (Cu), molybdenum (Mo), cobalt (Co), silver (Ag), platinum (Pt), nickel (Ni), chromium (Cr), gold (Au), germanium (Ge), magnesium (Mg), palladium (Pd), hafnium (Hf), zinc (Zn), vanadium (V), zirconium (Zr), a metal alloy thereof, and metal nitride thereof.

12. A substrate processing apparatus comprising:
a first chamber configured to accommodate a substrate therein; and
a second chamber including a laser source provided in an internal space thereof,
wherein the first chamber comprises
a substrate assembly configured to fix the substrate,
a target assembly configured to fix a target including a deposition material,
a first ion gun configured to irradiate an ion beam onto the target to discharge deposition particles, which are ions of the deposition material, to the substrate, and
a second ion gun configured to irradiate a hydrogen ion beam toward the substrate,
wherein the second ion gun comprises
a plasma generator configured to generate plasma,
a container configured to accommodate the plasma, and
a first grid electrode and a second grid electrode each configured to extract ions from the container, and
wherein the second chamber is configured to be provided with the substrate, on which the hydrogen ion beam has been irradiated, and perform thermal treatment on the substrate.

13. The substrate processing apparatus of claim 12, wherein the second chamber further comprises:
a support unit configured to fix the substrate; and
a beam delivery optical structure disposed between the support unit and the laser source, and
the beam delivery optical structure is configured to transfer light, irradiated from the laser source, to the substrate.

14. The substrate processing apparatus of claim 12, wherein the second grid electrode is disposed apart from the first grid electrode and receives a positive voltage of about 60 V to about 1,000 V.

15. The substrate processing apparatus of claim 12, wherein the second ion gun further comprises a third grid electrode disposed apart from the second grid electrode, and
the third grid electrode receives a voltage which is lower than a voltage of the second grid electrode.

16. The substrate processing apparatus of claim 12, wherein the plasma generator is configured to receive a processing gas so as to generate the plasma, and
the processing gas comprises hydrogen (H₂), helium (He), oxygen (O₂), nitrogen (N₂), argon (Ar), chromium (Cr), xenon (Xe), or a combination thereof.

17. The substrate processing apparatus of claim 16, wherein the processing gas is about 70% to about 100% in volume ratio of hydrogen (H₂).

18. The substrate processing apparatus of claim 16, wherein the target comprises one of tungsten (W), ruthenium (Ru), tantalum (Ta), titanium (Ti), aluminum (Al), copper (Cu), molybdenum (Mo), cobalt (Co), silver (Ag), platinum (Pt), nickel (Ni), chromium (Cr), gold (Au), germanium (Ge), magnesium (Mg), palladium (Pd), hafnium (Hf), zinc (Zn), vanadium (V), zirconium (Zr), a metal alloy thereof, and metal nitride thereof.

19. A substrate processing apparatus comprising:
a first chamber configured to accommodate a substrate therein and maintain a vacuum pressure of about 10⁻¹ Torr to about 10⁻⁹ Torr; and
a second chamber including a heater provided in an internal space thereof,
wherein the first chamber comprises
a substrate assembly configured to fix the substrate,
a target assembly configured to fix a target including a deposition material,
a first ion gun configured to irradiate an ion beam onto the target to discharge deposition particles, which are ions of the deposition material, to the substrate, and
a second ion gun configured to irradiate a hydrogen ion beam toward the substrate,
wherein the second ion gun comprises
a plasma generator configured to generate plasma,
a container configured to accommodate the plasma, and
a first grid electrode and a second grid electrode each configured to extract ions from the container,
wherein the second chamber is configured to be provided with the substrate, on which the hydrogen ion beam has been irradiated, and perform thermal treatment on the substrate,
wherein the heater is configured to supply heat to the substrate while maintaining a temperature of about 800° C. to about 1,200° C.,
wherein the plasma generator is configured to receive a processing gas so as to generate the plasma, and the processing gas comprises hydrogen (H₂), helium (He), oxygen (O₂), nitrogen (N₂), argon (Ar), chromium (Cr), xenon (Xe), or a combination thereof,
wherein the processing gas is about 70% to about 100% in volume ratio of hydrogen (H₂), and
wherein the target comprises one of tungsten (W), ruthenium (Ru), tantalum (Ta), titanium (Ti), aluminum (Al), copper (Cu), molybdenum (Mo), cobalt (Co), silver (Ag), platinum (Pt), nickel (Ni), chromium (Cr), gold (Au), germanium (Ge), magnesium (Mg), palladium (Pd), hafnium (Hf), zinc (Zn), vanadium (V), zirconium (Zr), a metal alloy thereof, and metal nitride thereof.

20. The substrate processing apparatus of claim 19, wherein the second grid electrode is disposed apart from the first grid electrode, receives a positive voltage of about 60 V to about 1,000 V, receives with a voltage which is higher than a voltage of the first grid electrode, and is electrically insulated from the first grid electrode,
the first grid electrode is electrically floated, and
each of the first grid electrode and the second grid electrode comprises at least one of a metal mesh, a carbon mesh, and a plated micro capillary.

21-25. (canceled)
